(19) United States
(12) Patent Application Publication
(10) Pub. No.: US 2025/0253144 A1
(43) Pub. Date: Aug. 7, 2025

(54) COETANEOUS DEPOSITION-ETCHING FOR BOTTOM-UP CARBON GAPFILL

(71) Applicant: Applied Materials, Inc., Santa Clara, CA (US)

(72) Inventors: Peiqi WANG, Campbell, CA (US); Tze-Yu LIN, Santa Clara, CA (US); Vamshi Krishna GADDAMEDI, Sunnyvale, CA (US); Anantha Venkataraman NAGARAJAN, Sunnyvale, CA (US); Abdul Aziz KHAJA, San Jose, CA (US)

(21) Appl. No.: 19/041,858

(22) Filed: Jan. 30, 2025

Related U.S. Application Data
(60) Provisional application No. 63/627,870, filed on Feb. 1, 2024.

(51) Int. Cl. H01L 21/02; C23C 16/04; C23C 16/26; H01L 21/3065

(52) U.S. Cl. CPC H01L 21/02274; C23C 16/045; C23C 16/26; H01L 21/02115; H01L 21/3065

(57) ABSTRACT

A method for forming a carbon gapfill layer on a substrate is provided. The method includes positioning a substrate with at least one feature disposed thereon in a processing volume of a process chamber, flowing a hydrocarbon precursor gas into the processing volume at a precursor flow rate, flowing an etchant gas into the processing volume at an etchant flow rate, and generating a RF plasma in the processing volume from the hydrocarbon precursor gas and the etchant gas to form the carbon gapfill layer in the at least one feature.

### CROSS-REFERENCE TO RELATED APPLICATIONS

This application claims priority to U.S. Provisional Application No. 63/627,870, filed Feb. 1, 2024, which is herein incorporated by reference in its entirety.

### BACKGROUND

### Field

Embodiments of the present disclosure generally relate to manufacture of semiconductor components and devices. More specifically, embodiments described herein provide methods for forming bottom-up carbon gapfill layers on a semiconductor surface using a coetaneous deposition and etch process.

### Description of the Related Art

In semiconductor processing, devices are being manufactured with continually decreasing feature dimensions. Often, features utilized to manufacture devices at these advanced technology nodes include high aspect ratio structures and it is often necessary to fill a gap between circuit elements/structures with a variety of materials. Examples where gapfill material layers are utilized include filling shallow trench isolation (STI), horizontal interconnects, vias between adjacent metal layers, inter-metal dielectric layers (ILD), pre-metal dielectrics (PMD), passivation layers, patterning applications, etc. As the width between the structures shrink, the gap between them often gets taller and narrower, making the gap more difficult to fill without the gapfill material being stuck on sidewalls and creating voids and weak seams. Furthermore, often times a single device or substrate will have multiple gaps of varying widths (e.g., critical dimensions (CD)) and/or aspect ratios that will need to be filled with the gapfill material.

Conventional chemical vapor deposition (CVD) techniques often experience an overgrowth of material at the top of the gap before it has been completely filled. This can create a void or seam in the gap where the depositing material has been prematurely cut off by the overgrowth; a problem sometimes referred to as bread-loafing. As device geometries shrink and thermal budgets are reduced, void-free and seam-free filling of high aspect ratio spaces becomes increasingly difficult due to limitations of existing deposition processes, especially for forming gapfill material layers to concurrently fill multiple gaps with different CDs and/or aspect ratios.

Accordingly, what is needed in the art are improved methods for forming gapfill material layers in trenches.

### SUMMARY

Embodiments described herein generally relate to processes for forming gapfill material layers. More specifically, embodiments described herein relate to processes for forming carbon gapfill layers using coetaneous deposition and etch processes. In one embodiment, a method for forming a carbon gapfill layer is provided. The method includes positioning a substrate with at least one feature disposed thereon on a substrate support in a processing volume of a process chamber. The method also includes flowing a hydrocarbon precursor gas into the processing volume at a precursor flow rate, flowing an etchant gas into the processing volume at an etchant flow rate, and generating a RF plasma in the processing volume from the hydrocarbon precursor gas and the etchant gas to form the carbon gapfill layer in the at least one feature.

In another embodiment, a method for forming a carbon gapfill layer is provided. The method includes positioning a substrate having at least one feature on a substrate support in a processing volume of a process chamber, flowing a hydrocarbon precursor gas into the processing volume at a precursor flow rate, and flowing an etchant gas into the processing volume at an etchant flow rate. In some embodiments, the precursor flow rate and the etchant flow rate are such that a precursor etchant ratio between the precursor flow rate and the etchant flow rate is between about 1:12 and about 1:20. The method also includes generating an RF plasma in the processing volume to form the carbon gapfill layer in the at least one feature. Forming the carbon gapfill layer using the generated RF plasma includes depositing a deposition species formed from the hydrocarbon precursor gas on the at least one feature, and concurrently etching with an etch species formed from the etchant gas some of the deposition species deposited on the at least one feature.

In yet another embodiment, a method for forming a carbon gapfill layer is provided. The method includes flowing at a precursor flow rate a hydrocarbon precursor gas into a processing volume of a process chamber having a substrate with at least one feature disposed thereon, flowing an etchant gas into the processing volume at an etchant flow rate, and flowing an argon gas into the processing volume. A precursor etchant ratio between the precursor flow rate and the etchant flow rate is between about 1:12 and about 1:20. The method also includes generating an RF plasma in the processing volume to form a deposition species from the hydrocarbon precursor gas and an etch species from the etchant gas, and concurrently depositing the deposition species on the at least one feature, and etching some of the deposition species deposited on the at least one feature with the etch species using the generated plasma to form the carbon gapfill layer in the at least one feature.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a process chamber, according to certain embodiments;

FIG. 2 is a schematic block diagram of a method for forming a carbon gapfill layer, according to certain embodiments;

FIGS. 3A-3D are partial schematic side cross-sectional views of a substrate during the method of FIG. 2, according to certain embodiments;

FIG. 4 is a partial schematic side cross-sectional view of a substrate during processing, according to certain embodiments; and

FIGS. 5A and 5B are schematic cross-sectional views of an exemplary gapfill layer formed on a substrate using the method in FIG. 2, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The following disclosure describes techniques for forming gap fill material layers in features, such as trenches formed on a substrate or a material layer disposed thereon. Certain details are set forth in the following description and figures to provide a thorough understanding of various embodiments of the disclosure. Other details describing well-known structures and systems often associated with plasma processing are not set forth in the following disclosure to avoid unnecessarily obscuring the description of the various embodiments.

Many of the details, dimensions, angles and other features shown in the figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

Embodiments described herein will be described below in reference to a PECVD deposition process that can be carried out using any suitable thin film deposition system. Examples of suitable systems include the CENTURA® systems which may use a DXZ® process chamber, PRECISION 5000@ systems, PRODUCER® systems, PRODUCER® GT™ systems, PRODUCER® XP Precision™ systems, PRODUCER® SE™ systems, Sym3® process chamber, and Mesa™ process chamber, all of which are commercially available from Applied Materials, Inc., of Santa Clara, California.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface.

In addition to film processing directly on the surface of the substrate itself, in the present disclosure, any of the processing steps disclosed may also be performed on an intermediate layer formed on the substrate as disclosed in more detail below, and the term “substrate surface” is intended to include such intermediate layer as the context indicates. Thus, for example, where a film/layer or partial film/layer has been deposited onto a substrate surface, the exposed surface of the newly deposited film/layer becomes the substrate surface.

Carbon-based film deposition has been used to provide gap fill material layers during semiconductor processing through vapor deposition process techniques, such as plasma enhanced chemical vapor deposition (PECVD). Most vapor deposition methods, including PECVD, utilize a blanket deposition process that generally deposits more gap fill material on top of the high aspect ratio structures and in the upper region of the trenches between the structures. This may form “top-hats” on the high aspect ratio structures that can block the trenches during the deposition process, as well as result in the upper portion of the trench near the opening prematurely closing. Formation of top-hats and/or the premature closing of the trench can cause seams or voids in the filled features thereby affecting the quality of the semiconductor device. For example, large seams may lead to high resistance, contamination, loss of filled materials, and otherwise degrade performance of integrated circuits.

Conventional carbon gap fill material layer deposition techniques currently lack a technique for precise control over carbon deposition within trenches to allow for a pure bottom-up deposition approach. As such, when filling multiple adjacent trenches with varying CDs and/or aspect ratios, gap fill material layers formed by blanket deposition techniques in trenches of differing CD or aspect ratios generally will each vary in quality which in turn can affect subsequent processing operations needing to be performed and/or circuit performance of the resulting device. For example, since wider trenches are generally also deeper, a lack of a pure bottom-up deposition process leads to increased likelihood of voids and seams being formed in the deposited gap fill material layer.

Embodiments of the present disclosure provide techniques for performing a coetaneous deposition and etch process to form a gapfill material layer, such as a carbon gapfill layer in a trench between adjacent vertical structures. In some embodiments, the coetaneous deposition and etch process includes providing deposition and etch species during processing for forming the carbon gapfill layer. Specifically, in some embodiments, methods of the present disclosure include providing deposition species (e.g., C₂H₂⁺) and etch species (e.g., H* ions) to concurrently deposit carbon on the inner surfaces of the trench and etch some of the carbon deposited on the substrate. In some embodiments, the etch species etch at least some of the deposited carbon on the sidewall surfaces of the trench and top surfaces of the vertical structures on opposite sides of the trench. In such embodiments, without being bound by theory, it was observed that the growth profile of the carbon gapfill layer in each of the trenches may be governed by the loading behavior (e.g. flux ratio) of the deposition and etch species provided during processing. The providing of the etch in species the methods of the present disclosure during deposition of the carbon gapfill layer in turn allows for a more bottom-up growth approach.

Methods of the present disclosure provide techniques for modulating the neutral-to-ion flux of the deposition and etch species during processing to control the deposition rate and growth profile of the carbon gapfill layer within the trench. In some embodiments, varying of one or more processing parameters, such as the RF power level, temperature, pressure, and the flow rate ratio of the precursor and etchant gases may be used to modulate the neutral-to-ion flux of the deposition and etch species.

Additionally, by providing a more bottom-up growth approach when forming the carbon gapfill layer in the trench, the present disclosure may provide for forming gapfill material layers, such as carbon gapfill layers, in trenches with wider CDs, as well in a plurality of trenches with varying CDs and/or aspect ratios, in a single processing operation. For example, modulating the flux of each of the deposition and etch species may allow for providing similar deposition rates of the carbon gapfill layer during processing when depositing in multiple trenches with different CDs or aspect ratios. Such modulation may provide for carbon gapfill layers with more planarity or uniform growth profiles between the respective trenches. In other embodiments, modulating the flux of each of the deposition and etch species may allow for increasing the deposition rate of the carbon gapfill layer during processing, such as for depositing in trenches with wider CDs. Accordingly, the disclosure described herein provides several benefits over conventional methods and techniques.

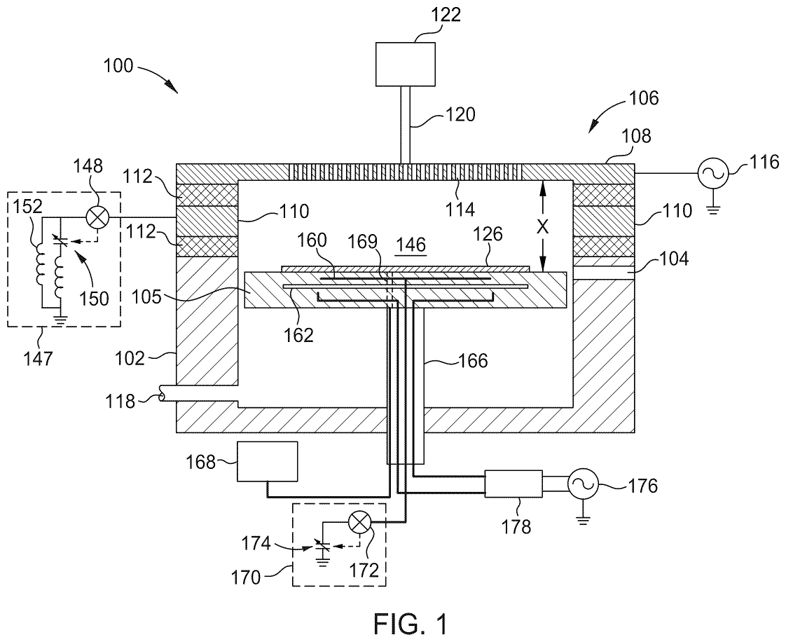

FIG. 1 is a schematic cross sectional view of a process chamber 100 configured according to various embodiments of the present disclosure. By way of example, the embodiment of the process chamber 100 in FIG. 1 is described in terms of a PECVD system, but any other process chamber may fall within the scope of the embodiments, including other plasma deposition chambers. One example of the process chamber 100 is a PRECISION™ chamber manufactured by Applied Materials, Inc., located in Santa Clara, Calif. It is to be understood that the chamber described below is an exemplary chamber and other chambers, including chambers from other manufacturers, may be used with or modified to accomplish aspects of the present disclosure.

The process chamber 100 includes a chamber body 102, a lid assembly 106, and a substrate support 105. The lid assembly 106 is disposed at an upper end of and is supported by the chamber body 102, and the substrate support 105 is at least partially disposed within the chamber body 102. The chamber body 102, lid assembly 106, and substrate support 105 together define a processing volume 146 within the process chamber 100 in which a substrate may be processed. The processing volume 146 may be accessed through a port 104 formed in the chamber body 102 that facilitates transfer of a substrate into and out of the processing volume 146 of the process chamber 100.

The lid assembly 106 includes a gas distributor 108, a modulation electrode 110, and insulators 112. The insulator 112, which may be a dielectric material such as a ceramic or metal oxide, for example aluminum oxide and/or aluminum nitride, contacts the modulation electrode 110 and separates the modulation electrode 110 electrically and thermally from the gas distributor 108 and from the chamber body 102. The gas distributor 108 (e.g., showerhead) has passages 114 therethrough for admitting process gas into the processing volume 146. A pair of insulators 112 (e.g., annular insulators) are disposed between the gas distributor 108 and the modulation electrode 110. The modulation electrode 110 is annular and circumscribes the processing volume 146.

Process gases (e.g., one or more precursor and one or more inert carrier gas) may be provided through the conduit 120 from a gas source 122 to be introduced into the process chamber 100. The processing gas from the conduit 120 enters the processing volume 146 through the passages 114 in the gas distributor 108 such that the processing gas is uniformly distributed in the processing volume 146. In one embodiment, the passages 114 in the gas distributor 108 may be radially distributed and gas flow to each of the passages 114 may be separately controlled to further facilitate gas uniformity within the processing volume 146.

The processing gases can be evacuated from the processing volume 146 through an outlet 118 which may be located at any convenient location along the chamber body 102. In some embodiments, the outlet 118 may be associated with a a vacuum pump (not shown) fluidly coupled to the processing volume 146. The vacuum pump may be part of the gas and pressure control system of the processing chamber 100.

In some embodiments, portions of the gas distributor 108 may be heated using a resistive heater (not shown) or thermal fluid disposed in a conduit (not shown) through a portion of the gas distributor 108 or otherwise in direct contact or thermal contact with the gas distributor 108. The conduit may be disposed through an edge portion of the gas distributor 108 to avoid disturbing the gas flow function of the gas distributor 108. Heating the edge portion of the gas distributor 108 may be useful to reduce the tendency of the edge portion of the gas distributor 108 to be a heat sink within the process chamber 100.

In some embodiments, the walls of the chamber body 102 may also be heated to similar effect. Heating the chamber surfaces exposed to the plasma also minimizes deposition, condensation, and/or reverse sublimation on the chamber surfaces, reducing the cleaning frequency of the chamber and increasing mean cycles per clean. Higher temperature surfaces also promote dense deposition that is less likely to produce particles that fall onto a substrate. Thermal control conduits with resistive heaters and/or thermal fluids (not shown) may be disposed through the chamber walls to achieve thermal control of the chamber walls. Temperature of all surfaces may be controlled by a controller.

In some embodiments, the gas distributor 108 may be coupled to a RF power source 116, such as a RF generator, as shown in FIG. 1. DC power, pulsed DC power, and pulsed RF power source may alternatively be used. In other embodiments, the gas distributor 108 may be coupled to ground. The RF power source 116 is electrically connected to the gas distributor 108 and is configured to apply a RF potential to the gas distributor 108 to facilitate the generation of plasma in the processing volume 146. In some embodiments, the RF power source 116 may be a high frequency RF power source (“HFRF power source”) capable of generating an HFRF power (e.g., at a frequency of about 13.56 MHZ). In other embodiments, the RF power source 116 may be a low frequency RF power source (“LFRF power source”) capable of generating an LFRF power (e.g., at a frequency of about 300 kHz). The LFRF power source can provide both low frequency generation and fixed match elements. The HFRF power source can be designed for use with a fixed match and can regulate the power delivered to the load, eliminating concerns about forward and reflected power. In further embodiments, an additional power source (not shown) may be added with the RF power source 116 to provide a dual RF power source to the process chamber 100.

The modulation electrode 110 may be coupled to a tuning circuit 147 that controls an impedance of an electrical path from the modulation electrode 110 to an electrical ground. The tuning circuit 147 comprises an electronic sensor 148 and an electronic controller, which may be a variable capacitor 150 as shown that is controllable by the electronic sensor 148. The tuning circuit 147 may be an LLC circuit comprising one or more inductors 152. The electronic sensor 148 may be a voltage or current sensor, and may be coupled to the variable capacitor 150 to afford a degree of closed-loop control of plasma conditions inside the processing volume 146. In some embodiments, the tuning circuit 147 may be any circuit that features a variable or controllable impedance under the plasma conditions present in the processing volume 146 during processing

The substrate support 105 may be disposed within the process chamber 100. The substrate support 105 may support a substrate 126 during processing. A first electrode 160 and a second electrode 162 are disposed in and/or on the substrate support 105. Further, in some embodiments, a heater element (not shown) may be embedded in the substrate support 105. The heater element can be operable to controllably heat the substrate support 105 and the substrate 126 positioned thereon to a target temperature, such as to maintain the substrate 126 at a temperature in a range from about 200 degrees Celsius to about 700 degrees Celsius.

The substrate support 105 is coupled to a shaft 166 for support. The shaft 166 can provide a conduit from a gas source 168 and electrical and temperature monitoring leads (not shown) between the substrate support 105 and other components of the process chamber 100. In some examples, a purge gas may be provided from the gas source 168 to the backside of the substrate 126 through one or more purge gas inlets 169 connected to the substrate support 105. The purge gas flowed toward the backside of the substrate 126 can help prevent particle contamination caused by deposition on the backside of the substrate 126. The purge gas may also be used as a form of temperature control to cool the backside of the substrate 126. Although not illustrated, the shaft 166 may be coupled to an actuator (not shown) which extends through a centrally-located opening formed in a bottom of the chamber body 102. The actuator may be flexibly sealed to the chamber body 102 by bellows (not shown) that prevent vacuum leakage from around the shaft 166. The actuator can allow the substrate support 105 to be moved vertically within the chamber body 102 between a process position and a lower, transfer position. The transfer position is slightly below the port 104 in the chamber body 102. In operation, the substrate support 105 may be elevated to a position in close proximity to the lid assembly 106 for processing.

The first electrode 160 may be embedded within the substrate support 105 or coupled to a surface of the substrate support 105. The first electrode 160 may be a plate, a perforated plate, a mesh, a wire screen, or any other distributed arrangement. The first electrode 160 may be a tuning electrode, and may be coupled to a tuning circuit 170. The tuning circuit 170 may have an electronic sensor 172 and an electronic controller, such as a variable capacitor 174 electrically connected between the first electrode 160 and an electrical ground. The electronic sensor 172 may be a voltage or current sensor, and may be coupled to the variable capacitor 174 to provide further control over plasma conditions in the processing volume 146.

The second electrode 162, which may be a bias electrode and/or an electrostatic chucking electrode, may be coupled to the substrate support 105. The second electrode 162 may be coupled to a bias power source 176 through an impedance matching circuit 178. The bias power source 176 may be DC power, pulsed DC power, RF power, pulsed RF power, or a combination thereof.

In operation, the substrate 126 is disposed on the substrate support 105, and process gases are flowed through the lid assembly 106 according to any desired flow plan. Electric power is coupled to the gas distributor to establish a plasma in the processing volume 146 between the gas distributor 108 and the substrate support 105. A distance or “spacing” between the bottom surface of the gas distributor 108 and a top surface of the substrate support 105 is represented by “x”. The substrate 126 may be subjected to an electrical bias using the bias power source 176, if desired.

Upon energizing a plasma in the processing volume 146, a potential difference is established between the plasma and the modulation electrode 110. A potential difference is also established between the plasma and the first electrode 160. The variable capacitors 150 and 174 may then be used to adjust the impedances of the paths to an electrical ground represented by the tuning circuits 147 and 170. A set point may be delivered to the tuning circuits 147 and 170 to provide independent control of the plasma density uniformity from center to edge and deposition rate. The electronic sensors may adjust the variable capacitors to maximize deposition rate and minimize thickness non-uniformity independently. The components implemented to control temperature and uniformity of the plasma, among other, can permit deposition of a highly conformal layer on a substrate being processed, even within small gaps.

Other deposition chambers may also benefit from the present disclosure and the parameters listed above may vary according to the particular deposition chamber used to form the amorphous carbon layer. For example, other deposition chambers may have a larger or smaller volume, requiring gas flow rates that are larger or smaller than those recited for deposition chambers available from Applied Materials, Inc. In one embodiment, methods of the present disclosure may be performed using a Precision™ process chamber, which is commercially available from Applied Materials, Inc., Santa Clara, California.

In general, the following exemplary PECVD process parameters may be used for the carbon gapfill layer formation process described herein. The processing temperature may range from a temperature inside the process chamber of about 200 degrees Celsius to about 1000 degrees Celsius (e.g., between about 300 degrees Celsius and about 600 degrees Celsius). The chamber pressure may range from about 1 Torr to about 10 Torr (e.g., between about 2 Torr and about 8 Torr; or between about 5 Torr and about 8 Torr). The RF power may be between 500 Watts and 1500 Watts at any RF (e.g., HFRF, LFRF, VHRF, etc.). In some embodiments, the RF power may be provided at a high frequency RF, such as 13.56 MHZ, or a low frequency RF, such as 300 KHz. The plate spacing between the top surface of the substrate 126 and the gas distributor 108 may be set to between about 300 mils to about 600 mils.

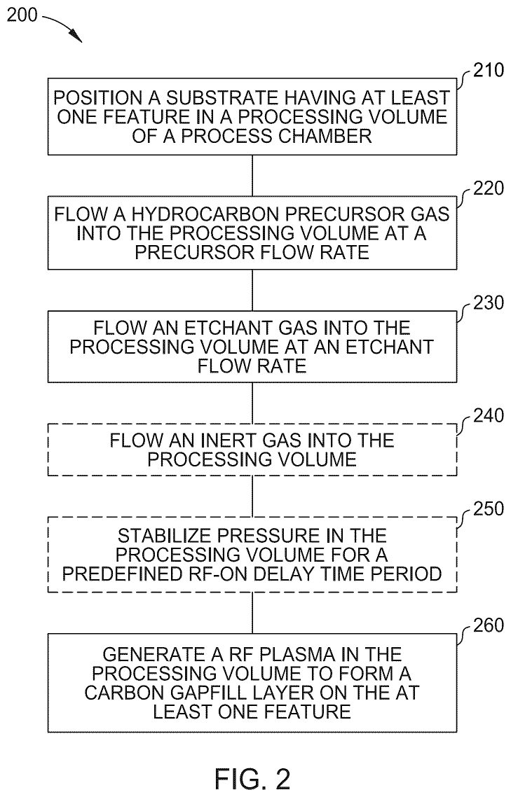

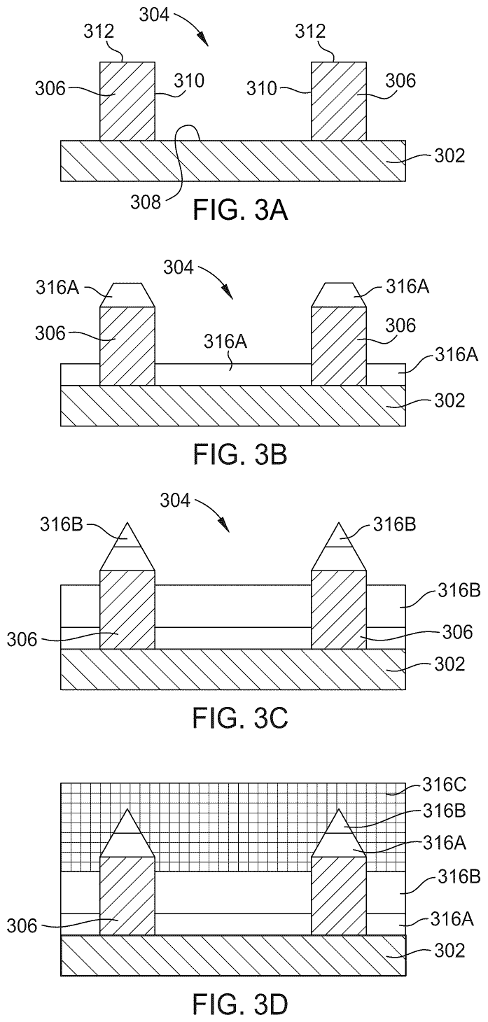

FIG. 2 depicts a process flow diagram of a method 200 for forming a carbon gapfill layer in a feature formed on a substrate, in accordance with one or more embodiments of the present disclosure. FIGS. 3A-3D depict schematic cross-sectional views of a substrate structure illustrating the carbon gapfill layer formation sequence according to method 200.

As used in this regard, the term “feature” means any intentional surface irregularity. The shape of the feature can be any suitable shape including, but not limited to, trenches and cylindrical vias. Suitable examples of features include, but are not limited to trenches which two sidewalls and a bottom surface, and vias which have a generally cylindrical sidewall. Other examples of features include without limitation, lines, contact holes, through-holes or other feature definitions utilized in a semiconductor, solar, or other electronic devices, such as high ratio contact plugs. The features can have any suitable aspect ratio (ratio of the depth of the feature to the width of the feature).

Although the method 200 is described below with reference to forming a carbon gapfill layer in a trench between structures formed on a substrate, the method 200 may also be used to advantage in other device manufacturing applications. Further, it should also be understood that the operations depicted in FIG. 2 may be performed simultaneously and/or in a different order than the order depicted in FIG. 2.

The method 200 begins at operation 210 by positioning a substrate 302, into a processing volume of a process chamber, such as the processing volume 146 of the process chamber 100 depicted in FIG. 1. The substrate 302 may be the substrate 126 depicted in FIG. 1. As shown in FIGS. 3A-3D, the substrate 302 includes at least one feature, such as a trench 304, formed between a pair of vertical structures 306 disposed on the substrate 302. The trench 304 includes a bottom surface 308 between sidewalls 310, and an opening between a top surface 312 of each of the vertical structures 306. In some embodiments, the trench 304 may be a negative feature formed directly in the substrate 302. Although FIGS. 3A-3D shows substrate 302 having a single trench 304 for illustrative purposes, those skilled in the art will understand that there can be more than one trench 304 each with the same or different CDs.

While the substrate 302 is illustrated as a single body, it is understood that the substrate 302 may contain one or more materials used in forming semiconductor devices such as metal contacts, trench isolations, gates, bitlines, or any other interconnect features. The substrate 302 may comprise one or more metal layers, one or more dielectric materials, semiconductor material, and combinations thereof utilized to fabricate semiconductor devices. For example, the substrate 302 may include an oxide material, a nitride material, a polysilicon material, or the like, depending upon application. The substrate 302 may be any substrate or material surface upon which film processing is performed. For example, the substrate 302 may be a material such as crystalline silicon, silicon oxide, silicon oxynitride, silicon nitride, strained silicon, silicon germanium, tungsten, titanium nitride, doped or undoped polysilicon, doped or undoped silicon wafers and patterned or non-patterned wafers, silicon on insulator (SOI), carbon doped silicon oxides, silicon nitrides, doped silicon, germanium, gallium arsenide, glass, sapphire, low-k dielectrics, and combinations thereof.

In an embodiment, the substrate, e.g., substrate 302, may be transferred into the process chamber 100 and onto the substrate support 105 by any suitable means, such as by substrate transfer port (not shown). The substrate support 105 can be adjusted to a processing position by an actuator (not shown). In some embodiments, the position of the substrate support 105 and the substrate 302 may be changed such that the spacing between the bottom surface of the gas distributor 108 and a top surface of the substrate support 105 is between about 200 mils and about 1,000 mils.

At operation 220, a hydrocarbon precursor gas is flowed into the processing volume 146. The hydrocarbon precursor gas may be flowed from the gas source 154 into the processing volume 146 through the gas distributor 108. During processing, the hydrocarbon precursor gas may be used to provide a deposition species for forming the carbon gapfill layer. In an embodiment, the hydrocarbon precursor gas includes a hydrocarbon compound having a general formula CₓH_{y}, where x has a range of between 1 and 20 and y has a range of between 1 and 20. Suitable carbon compounds include, for example, methane (CH₄), ethylene (C₂H₄), ethane (C₂H₆), butylenes (C₄H₈), cyclobutane (C₄H₈), and methylcyclopropane (C₄H₈). Suitable butylenes include, for example, 1-Butene, 2-Butene, and isobutylene. The hydrocarbon source can be any liquid or gas. In one embodiment, the hydrocarbon precursor gas includes acetylene (C₂H₂). In another embodiment, the hydrocarbon precursor gas includes propylene (C₃H₆). In one example, the hydrocarbon precursor gas is vapor at room temperature, which simplifies the hardware for material metering, control and delivery to the process chamber.

In some embodiments, the hydrocarbon precursor gas may further include a dilution gas. Suitable dilution gases such as helium (He), argon (Ar), or combinations thereof, may be added to the hydrocarbon precursor gas. Alternatively, dilution gases may not be used during the deposition.

In some embodiments, the flow rate of the hydrocarbon precursor gas may range from about 100 sccm to about 400 sccm. In some embodiments, the flow rate of the dilution gas may individually range from about 0 sccm to about 5,000 sccm (e.g., from about 2,000 sccm to about 4,000 sccm).

At operation 230, an etchant gas is flowed into the processing volume 146. The etchant gas may be flowed from the gas source 154 into the processing volume 146 through the gas distributor 108. In an embodiment, the etchant gas includes hydrogen gas (H₂) for providing H* radicals to etch portions of the carbon gapfill layer deposited during processing. In other embodiments, the etchant gas may be CO₂ or NH₃ gas. In some embodiments, the flow rate of the etchant gas is different from the flow rate of the hydrocarbon precursor gas. In some embodiments, the flow rate of the etchant gas may range from about 2000 sccm to about 6000 sccm.

At an optional operation 240, an inert gas, such as argon (Ar) may optionally be supplied with the hydrocarbon precursor gas and the etchant gas into the process chamber 100. In some embodiments, the flow rate of the argon gas is different from the hydrocarbon precursor gas and/or the etchant gas. In some embodiments, the flow rate of the argon gas may range from about 0 sccm to about 5,000 sccm. In some embodiments, argon may optionally be used for additional control over the deposition rate of the carbon gapfill layer. For example, when the carbon gapfill layer is being formed in multiple trenches of varying CDs, the deposition rate in trenches may vary as a result of the different CDs. Accordingly, argon may therefore be used to increase the deposition rate and provide for a more uniform deposition rate when depositing in multiple trenches with non-uniform CDs. In some embodiments, the addition of argon may also further assist in increased etching of deposition on the top surface 312 of the vertical structures 306 to reduce or minimize top-hat formation.

In an additional optional operation 250, the pressure in the processing volume is stabilized for a predefined RF-on delay time-period. The predefined RF-on delay time-period is a fixed time delay defined as the time-period between introduction of the various processing gas mixture into the processing volume in operations 220-240 and striking or generating the plasma in operation 260. Any suitable fixed time delay may be used to achieve targeted conditions. The length of the RF-on delay time period is typically selected such that the processing gas provided does not begin to thermally decompose or substantially thermally decompose in the processing volume.

At operation 260, RF plasma is generated in the processing volume 146 to form a carbon gapfill layer, such as a carbon gapfill layer 316 in the trench 304. In an embodiment, the plasma may be formed by capacitive means, and may be energized by coupling RF power into the processing gas mixture provided in operations 220-240.

FIG. 3B shows a carbon gapfill layer 316A deposited on the vertical structures 306 and on the bottom surface 308 of the trench 304 after processing for a first time period. Due to the coetaneous etching process occurring during operation 260, the carbon gapfill layer 316A does not form on the sidewalls 310 near the opening of the trench 304. Furthermore, the etching of the top surface 312 of the vertical structures 306 near the opening of the trench 304 curtails deposition on the vertical structures 306 and prevents the carbon gapfill layer 316A from building up and extending outwards over the opening of the trench 304 (e.g., formation of top-hats). FIG. 3C shows a carbon gapfill layer 316B formed over the carbon gapfill layer 316A after processing for a subsequent second time period, and FIG. 3D shows a carbon gapfill layer 316C formed over the carbon gapfill layer 316B after a further subsequent third time period of processing. As shown in FIGS. 3B-3D, the coetaneous deposition and etching process provides a controllable bottom-up growth approach for forming carbon gapfill layers in features on a substrate, such as trenches.

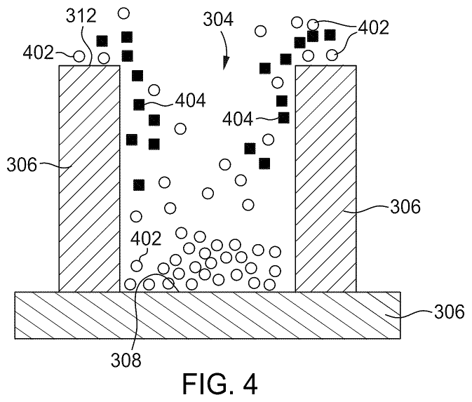

FIG. 4 shows a schematic view of the processing by plasma species generated in operation 260 to form a carbon gapfill layer in the trench 304. As shown, plasma species from the RF plasma generated from the processing gases in the process chamber 100 is correspondingly used to simultaneously deposit and etch the carbon gapfill layer 316 on the substrate 302. During processing, the disassociation of the hydrocarbon precursors in the plasma results in the deposition of deposition species 402 (e.g., C₂H₂⁺ or hydrocarbon ions) on the substrate 302, including the bottom surface 308 of the trench 304 and on the top surface 312 of the vertical structures 306. The plasma generated from the processing gases simultaneously also causes the etchant gas to dissociate resulting in etching species 404 (e.g., hydrogen radicals) that etch portions of the carbon gapfill layer 316 being deposited in the trench 304. The etching by the etching species 404 in turn minimizes the deposition or buildup of the deposition species 402 on the vertical structures 306 near the opening of the trench 304 and prevents the formation of top-hats on the vertical structures 306. The etching by the etching species 404 also prevents deposition on the sidewalls 310 within the trench 304 which prevents bread-loafing from occurring during operation 260.

It was observed that varying the RF power and/or a precursor etchant ratio between the flow rate of the hydrocarbon precursor gas and the flow rate of the etchant gas during processing can be used to modulate the ion-to-neutral flux of the deposition (e.g., carbon, hydrocarbon) and etch (e.g. hydrogen radical) species. In some embodiments, the RF power plays a role by changing the ion-to-neutral flux ratio of the deposition and etch species. In some embodiments, the RF power may have a high frequency (e.g., 13.6 MHZ, 27 MHz, 40 MHZ) or a low frequency (e.g., 200 kHz). In other embodiments, the RF power may be a dual-frequency RF power that has a high frequency component and a low frequency component. The RF power may be typically applied at a power level between about 500 W and about 1,500 W (e.g., between about 600 W and about 1000 W), which may be all high-frequency RF power, for example at a frequency of about 13.56 MHZ, or may be a mixture of high-frequency power and low frequency power, for example, at a frequency of about 300 KHz.

In some embodiments, the RF Power may be varied to adjust the deposition rate of the carbon gapfill layer 316 in the trenches 304. Adjusting the deposition rate provides advantages, particularly for forming the carbon gapfill layer 316 concurrently in multiple trenches with varying CDs and aspect ratios. Without being bound by theory, for example, it was observed that lowering RF Power may generally provide for more uniform deposition rate when concurrently depositing in multiple trenches with varying CDs and/or aspect ratios. In some embodiments, the role of the RF power may also vary at different processing temperatures as processing temperature also separately affects the behavior of the deposition and etch species during processing.

As mentioned above, in some embodiments, the flow rate of the hydrocarbon precursor gas may range from about 100 sccm to about 400 sccm, and the flow rate of the etchant gas may range from about 2000 sccm to about 6000 sccm. In some embodiments, the flow rate of the hydrocarbon precursor gas and/or the etchant gas may be adjusted to vary the precursor etchant ratio to modulate the ion-to-neutral flux of the respective deposition (e.g., carbon) and etch (e.g. hydrogen radical) species during the deposition process. In some embodiments, the precursor etchant ratio during processing may range from about 1:6 to about 1:20, such as 1:6, 1:12, 1:14, 1:16, and 1:20. For example, in one embodiment, the precursor etchant ratio may be about 1:16 in which the flow rate of the hydrocarbon precursor gas may be about 295 sccm and the flow rate of the etchant gas may be about 4800 sccm.

The precursor etchant ratio used may be based on the size and structures of the trenches 304 and vertical structures 306. In some embodiments, the precursor etchant ratio may be adjusted to tune the deposition and growth profile of the carbon gapfill layer. In some embodiments, the precursor etchant ratio may be adjusted by correspondingly adjusting the flow rate hydrocarbon precursor gas and/or the etchant gas. For example, generally, and without being bound by theory, increasing the flow rate of the etchant gas provides for a lower precursor etchant ratio which may be used to tailor “top-hat” growth on the vertical structures 306 or further minimize deposition on the sidewalls 310 during processing.

During formation of the carbon gapfill layer, the chamber, the substrate, or both may be maintained at a temperature between about 200 degrees Celsius and about 700 degrees Celsius (e.g., between about 400 degrees Celsius to about 600 degrees Celsius; or between about 500 degrees Celsius to about 700 degrees Celsius). The chamber pressure may range from about 1 Torr to about 10 Torr (e.g., between about 2 Torr and about 8 Torr; or between about 4 Torr and about 8 Torr). The distance between the substrate support 105 and gas distributor 108 (e.g., spacing x in FIG. 1) may be set to between about 200 mils and about 600 mils, for example, about 500 mils.

For most applications, the plasma is maintained for a time period to form the carbon gapfill layer 316 in the trench 304. The process of operation 260 may be performed simultaneously, sequentially or may partially overlap with the processes of operations 220-250. In some embodiments, the flow of each of the processing gases (e.g., the hydrocarbon precursor gas and the etchant gas) may be stopped when each of the trench 304 is sufficiently filled. In some embodiments, the process disclosed can also planarize the field surface after the trench 304 is filled, thereby reducing the need for, and possibly even avoid altogether, any subsequent chemical mechanic polishing (CMP) process to prepare and flatten the surface for forming of subsequent optical structures. In some embodiments, the flow of each of the processing gases may be stopped when the carbon gapfill layer 316 above the trench 304 is sufficiently planarized. Any excess process gases and by-products from the deposition of the season layer may then be removed from the processing volume by performing an optional purge/evacuation process.

In some embodiments, the carbon gapfill layer 316 may be deposited to fill trenches with aspect ratios as low as 9:1. In some embodiments, the aspect ratio of the trench may be greater than or equal to about 9:1, 10:1, 15:1, 20:1, 25:1, 30:1, 35:1 or 40:1. In further embodiments, the carbon gapfill layer 316 may be formed in multiple trenches each with different aspect ratios.

The coetaneous deposition and etch process during operation 260 provides for a more tunable and bottom-up gapfill approach. Advantageous of such an approach includes minimizing deposition on sidewalls of the trench to prevent bread-loafing during processing, self-planarization even when depositing the carbon gapfill layer in dense patterned layers, and providing a bottom-up deposition approach in trenches with aspect ratios as low as 9:1. In some embodiments, coetaneous deposition and etch process also provides for filling multiple trenches simultaneously, the multiple trenches having the same or different CDs and/or aspect ratios. Being able to adjust and tune deposition parameters based on the growth profile and specific trench numbers and dimensions the carbon gapfill layer is to be deposited in also provides each of the advantages above when depositing in multiple trenches.

In general, it was observed that the when depositing in multiple trenches with varying CDs and/or aspect ratios, the deposition rate in each of the respective trenches is dependent on the specific CD and/or aspect ratio. Generally, the deposition rate in a trench with a larger CD will be higher than a trench with a lower CD. The precursor etchant ratio may therefore be adjusted based on the deposition desired and the variations in CD and/or aspect ratio of the trenches. In some embodiments, the RF power and the processing temperature also affects the behavior of the deposition and etching species components. As such, the required adjustments for modifying precursor etchant ratio varies based on the specific RF power applied and the process chamber. For example, co-flow requirements for the etchant gas decreases at higher temperatures since the etching by the etch species increases with temperature. Without being bound by theory, a higher precursor etchant ratio (e.g., closer to 1:20) provides for improved film quality in the gapfill layer formed in each of the trenches. However, the varying trench sizes can lead to poorer planarity or growth profile uniformity between the trenches. In contrast, decreasing the precursor etchant ratio (e.g., closer to 1:12) provides for more similar deposition rate in each of the trenches resulting in a more uniform growth profile. However, the low co-flow at the lower precursor etchant ratio gives rise to a higher deposition rate in trenches with larger CDs, thereby resulting in increased chance of formation of voids in the trenches with larger CDs.

The following non-limiting examples are provided to further illustrate embodiments described herein. However, the examples are not intended to be all inclusive and are not intended to limit the scope of the embodiments described herein

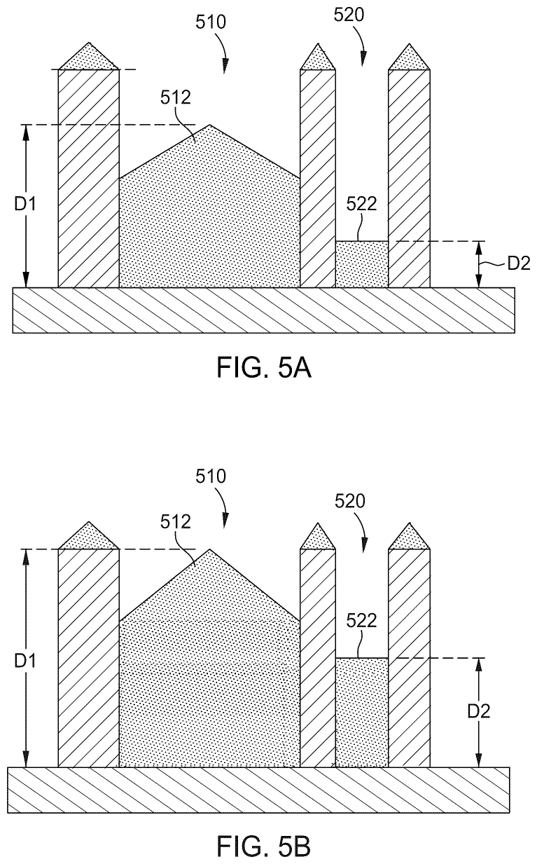

FIGS. 5A and 5B illustrate a schematic cross-sectional view of exemplary gapfill layers formed in adjacent trenches utilizing the method 200, according to certain embodiments. Specifically, a deposition process with the precursor etchant ratio at about 1:20 was performed to form a gapfill layer in a first trench 510 and an adjacent second trench 520. In the embodiment shown, the first trench 510 has a CD of about 350 nm and the second trench 520 has a CD of about 25 nm. Processing parameters to form a carbon gapfill layer 512 in the first trench 510 and a carbon gapfill layer 522 in the second trench 520 include a processing temperature of about 220 degrees Celsius at a pressure of about 4.5 Torr. The spacing between the substrate support and gas distribution showerhead (e.g., spacing x in FIG. 1) was about 530 mil. Processing gases provided to the process chamber for the coetaneous deposition and etch process included propylene gas (C₃H₆) flowed at 295 sccm for providing the precursor for the deposition species, He gas flowed at 200 sccm as a dilution gas, and H2 gas flowed 4800 sccm for providing the etching species. As shown in FIG. 5A, a deposition rate ratio between a height D1 of the carbon gapfill layer 512 and a height D2 of the carbon gapfill layer 522 formed in the first and second trenches 510, 520, respectively, is about 2.56 (e.g., 195 nm/76 nm).

In contrast, by lowering the precursor etchant ratio (e.g., to about 1:14), the deposition rate may be tuned to provide for improved planarity within the trenches. For example, under the same processing parameters as described above with respect to FIG. 5A but with the flow rate of the propylene gas (C₃H₆) increased to 345 sccm, the precursor etchant ratio was correspondingly decreased to about 1:14. As shown in FIG. 5B, the deposition rate ratio between the carbon gapfill layer 512 and the carbon gapfill layer 522 decreases to about 2.09 (e.g., 240 nm/115 nm). The increased deposition rate due to the lower precursor etchant ratio improved uniformity of the growth profile between the first trench 510 and the second trench 520.

While the foregoing is directed to embodiments of the present disclosure, other and further embodiments of the disclosure may be devised without departing from the basic scope thereof, and the scope thereof is determined by the claims that follow.

What is claimed is:

1. A method for forming a carbon gapfill layer, comprising:
positioning a substrate with at least one feature disposed thereon on a substrate support in a processing volume of a process chamber;
flowing a hydrocarbon precursor gas into the processing volume at a precursor flow rate;
flowing an etchant gas into the processing volume at an etchant flow rate; and
generating a RF plasma in the processing volume from the hydrocarbon precursor gas and the etchant gas to form the carbon gapfill layer in the at least one feature.

2. The method of claim 1, wherein a precursor etchant ratio between the precursor flow rate and the etchant flow rate is between about 1:12 and about 1:20.

3. The method of claim 1, wherein generating the RF plasma to form the carbon gapfill layer comprises concurrently depositing a deposition species formed from the hydrocarbon precursor gas on the at least one feature, and etching with an etch species formed from the etchant gas some of the deposition species deposited on the at least one feature.

4. The method of claim 1, wherein the hydrocarbon precursor gas comprises acetylene (C₂H₂) or propylene (C₃H₆).

5. The method of claim 1, wherein the etchant gas comprises hydrogen (H₂), carbon dioxide (CO₂), or ammonia (NH₃).

6. The method of claim 1, wherein generating the RF plasma comprises applying an RF power to the processing volume to form a deposition species from the hydrocarbon precursor gas and an etch species from the etchant gas, wherein the RF power is between about 500 Watts and 1500 Watts.

7. The method of claim 1, further comprising flowing a dilution gas comprising helium (He) or argon (Ar).

8. The method of claim 1, wherein a pressure inside the processing volume is between about 1 Torr and about 10 Torr.

9. The method of claim 1, wherein a temperature inside the processing volume is between about 300 degrees Celsius and about 600 degrees Celsius.

10. The method of claim 1, wherein a distance between a gas distributor positioned in the processing volume and the substrate support is between about 200 mils and about 600 mils.

11. The method of claim 1, wherein the at least one feature comprises a trench having an aspect ratio greater than or equal to about 9:1.

12. A method for forming a carbon gapfill layer, comprising:
positioning a substrate having at least one feature on a substrate support in a processing volume of a process chamber;
flowing a hydrocarbon precursor gas into the processing volume at a precursor flow rate;
flowing an etchant gas into the processing volume at an etchant flow rate, wherein a precursor etchant ratio between the precursor flow rate and the etchant flow rate is between about 1:12 and about 1:20; and
generating an RF plasma in the processing volume to form the carbon gapfill layer in the at least one feature, wherein the carbon gapfill layer is formed by depositing a deposition species formed from the hydrocarbon precursor gas on the at least one feature, and concurrently etching with an etch species formed from the etchant gas some of the deposition species deposited on the at least one feature.

13. The method of claim 12, wherein the hydrocarbon precursor gas comprises acetylene (C₂H₂) or propylene (C₃H₆).

14. The method of claim 12, wherein the etchant gas comprises hydrogen (H₂), carbon dioxide (CO₂), or ammonia (NH₃).

15. The method of claim 12, further comprising flowing a dilution gas comprising helium (He) or argon (Ar).

16. The method of claim 12, wherein generating the RF plasma comprises applying an RF power to the processing volume, wherein the RF power is between about 500 Watts and 1500 Watts.

17. The method of claim 12, wherein the at least one feature comprises a plurality of trenches with non-uniform CDs and/or aspect ratios.

18. A method for forming a carbon gapfill layer, comprising:
flowing at a precursor flow rate a hydrocarbon precursor gas into a processing volume of a process chamber having a substrate with at least one feature disposed thereon;
flowing an etchant gas into the processing volume at an etchant flow rate, wherein a precursor etchant ratio between the precursor flow rate and the etchant flow rate is between about 1:12 and about 1:20;
flowing an argon gas into the processing volume;
generating an RF plasma in the processing volume to form a deposition species from the hydrocarbon precursor gas and an etch species from the etchant gas; and
concurrently depositing the deposition species on the at least one feature, and etching with the etch species some of the deposition species deposited on the at least one feature using the RF plasma to form the carbon gapfill layer in the at least one feature.

19. The method of claim 18, further comprising decreasing the precursor flow rate to increase the precursor etchant ratio when forming the carbon gapfill layer to increase a deposition rate of the carbon gapfill layer in the at least one feature.

20. The method of claim 18, wherein the at least one feature comprises a plurality of trenches with non-uniform CDs, and forming the carbon gapfill layer further comprises increasing the precursor flow rate to decrease the precursor etchant ratio to increase uniformity in deposition rates of the carbon gapfill layer in each of the plurality of trenches.
